(19) United States
(12) Patent Application Publication
(10) Pub. No.: US 2010/0223527 A1
(43) Pub. Date: Sep. 2, 2010

(54) DATA PROTECTION CIRCUIT, DATA PROTECTION METHOD, AND DATA PROCESSING APPARATUS

(75) Inventors: Daisuke KAWAKAMI, Kanagawa (JP); Takeshi AKIYAMA, Shizuoka (JP); Takahiro SUZUKI, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/714,999

(22) Filed: Mar. 1, 2010

(30) Foreign Application Priority Data
Mar. 2, 2009 (JP) 2009-048048

(51) Int. Cl. H03M 13/00

(52) U.S. Cl. 714/758; 714/752; 714/E11.03

(57) ABSTRACT

A generation unit in a data protection circuit acquires input data from one position on a path that outputs the input data as output data, and generates a second error detecting code. A check unit acquires the input data from another position on the path that is closer to an output side than the acquiring position in the generation unit, and checks the input data using a first error detecting code. Further, a connection unit connects the acquiring position in the generation unit and the acquiring position in the check unit so that the input data is acquired by the check unit subsequent to acquirement by the generation unit.

### INCORPORATION BY REFERENCE

This application is based upon and claims the benefit of priority from Japanese patent application No. 2009-048048, filed on Mar. 2, 2009, the disclosure of which is incorporated herein in its entirety by reference.

### BACKGROUND

1. Field of the Invention

The present invention relates to a data protection circuit, a data protection method, and a data processing apparatus, and more particularly, to a technique of converting an error detecting code used for data protection.

2. Description of Related Art

A typical data processing apparatus including a function of converting an error detecting code is disclosed in Japanese Unexamined Patent Application Publication No. H06-324951 (Kramer et al.), for example. FIG. 12 shows the configuration of the data processing apparatus disclosed by Kramer et al.

A data processing apparatus 1x shown in FIG. 12 includes a processor 2, a parity logic circuit 400, an ECC (Error Correcting Code) logic circuit 500, and a memory 3. The processor 2 processes data Dx. The parity logic circuit 400 is connected to the processor 2 via a system bus B1. The memory 3 is connected to the ECC logic circuit 500 via a memory bus B2, and stores the data Dx. On the system bus B1, the data Dx is protected by adding a parity C2 thereto. On the other hand, on the memory bus B2, the data Dx is protected by adding an ECC C1 thereto.

In writing the data to the memory 3 by the processor 2, the parity logic circuit 400 firstly checks the data Dx input from the processor 2 using the parity C2 input according thereto. Then, the parity logic circuit 400 removes the parity C2, and transfers only the data Dx to the ECC logic circuit 500. The ECC logic circuit 500 generates the ECC C1 corresponding to the data Dx, and transfers the ECC C1 with the data Dx to the memory 3.

Meanwhile, in reading the data from the memory 3 by the processor 2, the ECC logic circuit 500 firstly checks the data Dx read out from the memory 3 using the ECC C1 read out according thereto. Then, the ECC logic circuit 500 removes the ECC C1, and transfers only the data Dx to the parity logic circuit 400. The parity logic circuit 400 generates the parity C2 corresponding to the data Dx, and transfers the parity C2 with the data Dx to the processor 2.

### SUMMARY

However, the present inventors have found a problem in the technique disclosed by Kramer et al. that data protection performed in the process of converting the error detecting code is insufficient. This is generally because data protection is not performed in a section between the parity logic circuit 400 and the ECC logic circuit 500 (hereinafter called unprotected section) SCTn, as shown in FIG. 13.

More specifically, it is assumed that, in reading the data from the memory 3, hardware failure or a soft error due to disturbance from other circuits (neutron rays, a rays, etc.) is occurred in a path between the parity logic circuit 400 and the ECC logic circuit 500, and thus bit corruption is occurred in the data Dx (step S1). In such a case, the parity logic circuit 400 generates the parity C2 based on the invalid data Dx (step S2). Thus, there is no way for the processor 2 to detect that the data Dx read out from the memory 3 is invalid (step S3). Although it is not shown in the drawings, the ECC logic circuit 500 generates the ECC C1 based on the invalid data Dx in which bit corruption is occurred in writing the data to the memory 3. Accordingly, even after the hardware failure or the soft error is restored, the invalid data Dx is processed as it is when the data is again read out from the memory 3.

A first exemplary aspect of the present invention is a data protection circuit to which input data and a first error detecting code are input, the data protection circuit outputting output data corresponding to the input data and a second error detecting code. This data protection circuit includes a path that outputs the input data as the output data, a generation unit that acquires the input data from the path and generates the second error detecting code, and a check unit that acquires the input data from a position on the path that is closer to an output side than an acquiring position in the generation unit and checks the input data using the first error detecting code.

A second exemplary aspect of the present invention is a data processing apparatus including first and second processing circuits, each of which processing data, and a protection circuit to which data and a first error detecting code are input from the first processing circuit, the protection circuit outputting the data and a second error detecting code to the second processing circuit. The protection circuit generates the second error detecting code corresponding to the data, and thereafter checks the data using the first error detecting code.

A third exemplary aspect of the present invention is a data protection method including generating a first error detecting code corresponding to data that is input, and then checking the data using a second error detecting code input according to the data.

In summary, according to the present invention, the input data is doubly protected by error detecting codes that are different from each other in the process of converting the error detecting code. Hence, it is possible to detect the occurrence of the above-described invalid data with higher accuracy.

According to the present invention, it is possible to provide sufficient data protection in the process of converting the error detecting code, thereby enhancing the reliability of the data processing apparatus.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing a configuration example of a data processing apparatus that is common to each of exemplary embodiments according to the present invention;

FIG. 2 is a block diagram showing a configuration example of a data protection circuit according to a first exemplary embodiment of the present invention;

FIG. 3 is a table showing an operation example of the data protection circuit according to the first exemplary embodiment of the present invention;

FIG. 4 is a block diagram showing a configuration example of a data protection circuit according to a second exemplary embodiment of the present invention;

FIG. 5 is a table showing an operation example of the data protection circuit according to the second exemplary embodiment of the present invention;

FIG. 6 is a block diagram showing a configuration example of a data protection circuit according to a third exemplary embodiment of the present invention;

FIG. 7 is a block diagram showing a configuration example of a data protection circuit according to a fourth exemplary embodiment of the present invention;

FIG. 8 is a table showing an operation example of the data protection circuit according to the fourth exemplary embodiment of the present invention;

FIG. 9 is a block diagram showing a configuration example of a data protection circuit according to a fifth exemplary embodiment of the present invention;

FIG. 10 is a table showing an operation example of the data protection circuit according to the fifth exemplary embodiment of the present invention;

FIG. 11 is a block diagram showing a configuration example of a data protection circuit according to a sixth exemplary embodiment of the present invention;

FIG. 12 is a block diagram showing a configuration example of a typical data processing apparatus; and

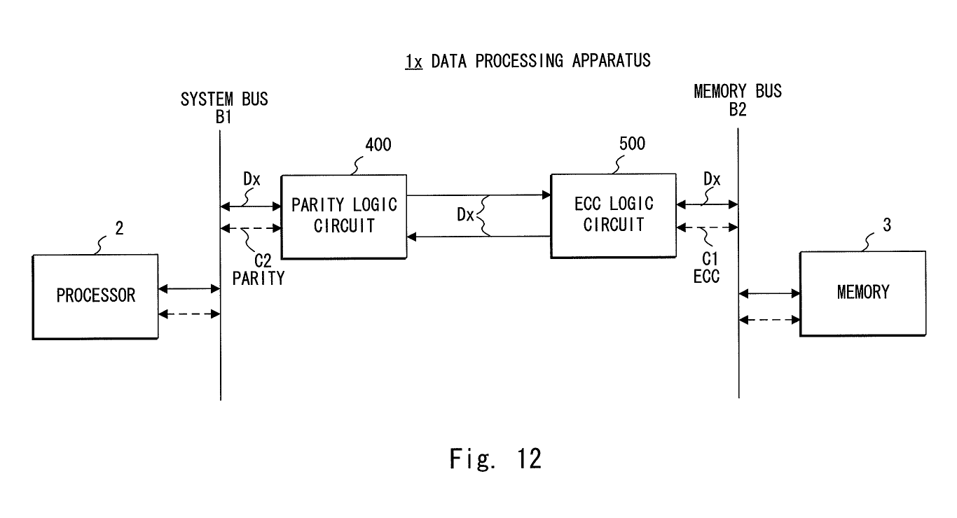

FIG. 13 is a diagram for explaining a problem of the typical data processing apparatus.

### DETAILED DESCRIPTION OF THE EXEMPLARY EMBODIMENTS

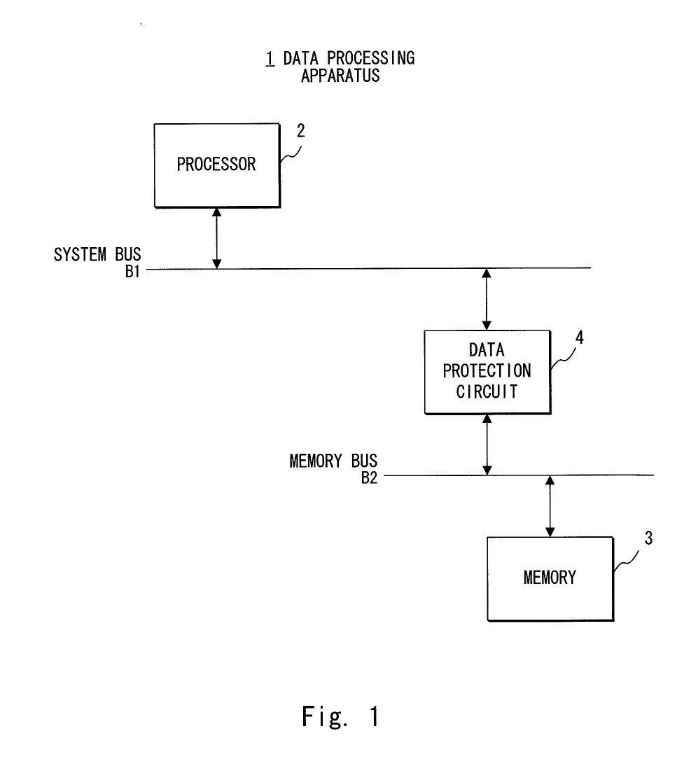

Hereinafter, in first to sixth exemplary embodiments, data protection circuits according to the present invention and data processing apparatus to which each data protection circuit is applied will be described with reference to FIGS. 1 to 11. Throughout the drawings, the same components are denoted by the same reference symbols, and overlapping description will be omitted as appropriate for the sake of clarity.

### First Exemplary Embodiment

As shown in FIG. 1, a data processing apparatus 1 according to the first exemplary embodiment includes a processor 2 such as a CPU (Central Processing Unit) or a DMA (Direct Memory Access) controller, a memory 3 such as an SRAM (Static Random Access Memory), and a data protection circuit 4. The processor 2 and the data protection circuit 4 are connected to each other by a system bus B1. Further, the memory 3 and the data protection circuit 4 are connected to each other by a memory bus B2. Data protection circuits according to second to sixth exemplary embodiments can be applied to the data processing apparatus 1, as is similar to the data protection circuit 4.

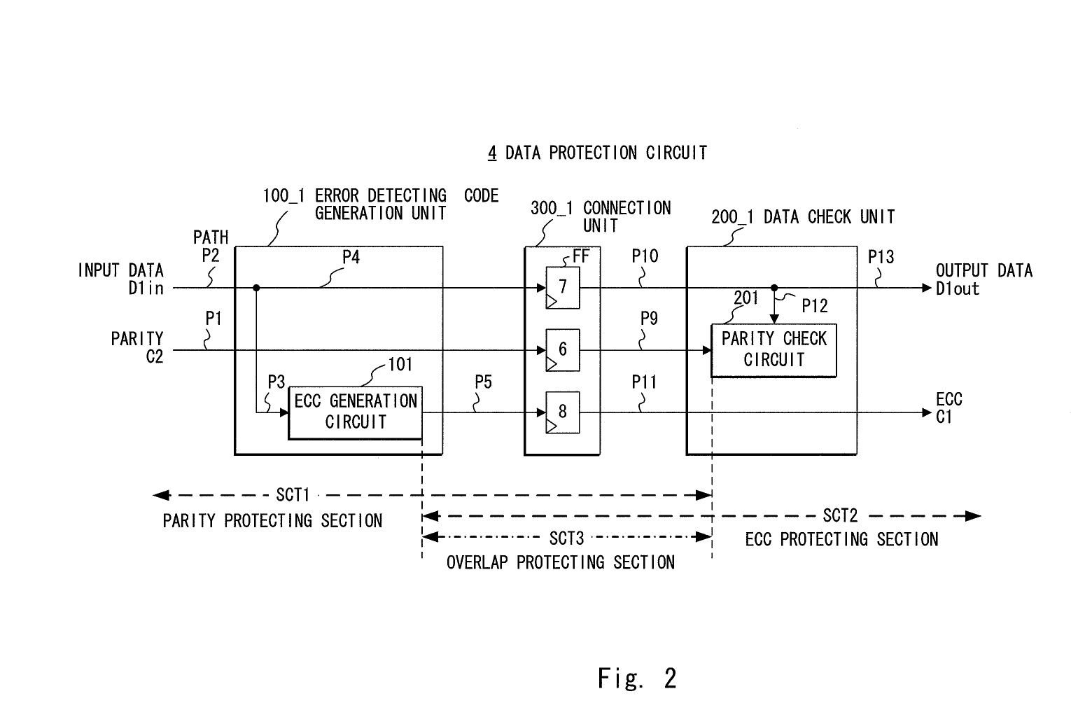

Further, as shown in FIG. 2, the data protection circuit 4 includes an error detecting code generation unit 100_1, a data check unit 200_1, and a connection unit 300_1. The connection unit 300_1 connects the generation unit 100_1 and the check unit 200_1. Now, the connection unit 300_1 prevents an order of acquiring data D1in by the generation unit 100_1 and the check unit 200_1 (the generation unit 100_1 acquires the data first, and thereafter the check unit 200_1 does) from being reversed due to the optimization (logic synthesis) in a process of mounting the data protection circuit 4. However, the connection unit 300_1 is not necessarily provided as long as the order of acquiring the data D1in is surely observed. This is also applied to connection units used in the second to sixth exemplary embodiments.

The error detecting code generation unit 100_1 includes an ECC generation circuit 101. The ECC generation circuit 101 generates ECC C1 corresponding to the data D1in input through the system bus B1. Further, the data check unit 200_1 includes a parity check circuit 201. The parity check circuit 201 checks the input data D1in using a parity C2 input according thereto. Note that it is not always necessary to employ the ECC and the parity as the error detecting codes, but various types of error detecting codes can be employed. Error detecting code generation units and data check units employed in the second to sixth exemplary embodiments will be structured in a similar way.

Further, the connection unit 300_1 includes three flip-flops (hereinafter abbreviated as FFs) 6 to 8. The FF 6 transfers the parity C2 that is input to the parity check circuit 201. Further, the FF 7 supplies the input data D1in to the parity check circuit 201 and outputs the input data D1in as output data D1out of the data protection circuit 4. The output data D1out is transferred to the memory 3 through the memory bus B2 described above. Further, the FF 8 transfers the ECC C1 output from the ECC generation circuit 101 to the memory 3 through the memory bus B2. Note that the connection unit 300_1 may be formed with buffers or the like, instead of the FFs. The connection units employed in the second to sixth exemplary embodiments will be structured in a similar way.

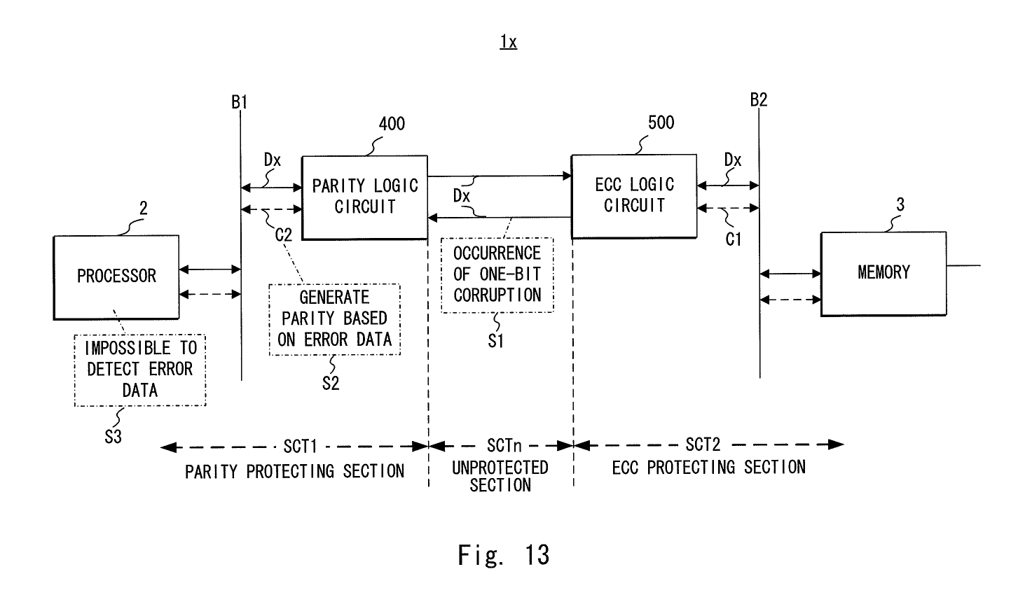

Accordingly, as shown in FIG. 2, the previous stage of the parity check circuit 201 corresponds to a parity protecting section SCT1, and the subsequent stage of the ECC generation circuit 101 corresponds to an ECC protecting section SCT2. Further, the section between the ECC generation circuit 101 and the parity check circuit 201 corresponds to an overlap section (hereinafter referred to as overlap protecting section) SCT3 of the data protection by the ECC and the data protection by the parity. In short, in the data protection circuit 4, there is no unprotected section SCTn as shown in FIG. 13 in writing the data into the memory 3. Accordingly, occurrence of the invalid data can be detected with higher accuracy.

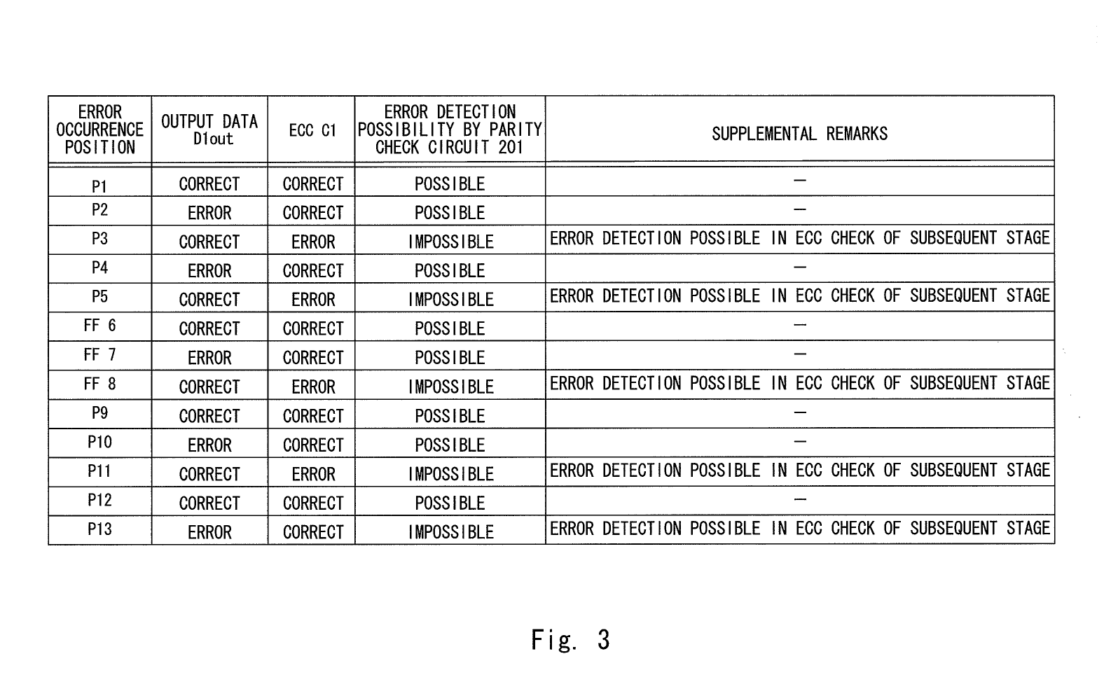

Hereinafter, the operation of this exemplary embodiment will be described with reference to FIG. 3. FIG. 3 shows an operation example when one-bit error is occurred in each of the paths P1 to P5 and P10 to P13, and the FFs 6 to 8 shown in FIG. 2.

When the error is occurred in any of the paths P1 (including system bus B1) and P9, and the FF 6, the data protection circuit 4 normally generates the output data D1out and the ECC C1. Further, the parity check circuit 201 in the data protection circuit 4 checks the input data D1in using a parity having an error (hereinafter referred to as error parity) C2. Accordingly, the parity check circuit 201 is able to detect the occurrence of the error in the path of the previous stage.

When the error is occurred in the path P2 (including system bus B1), the data protection circuit 4 generates the output data having the error (hereinafter referred to as error output data) D1out. Further, the ECC generation circuit 101 in the data protection circuit 4 treats the input data having the error (hereinafter referred to as error input data) D1in as normal data, and normally generates ECC C1. However, the parity check circuit 201 checks the error input data D1in using the normal parity C2. Accordingly, the parity check circuit 201 is able to detect that the error is occurred in the path of the previous stage.

When the error is occurred in the path P3, the data protection circuit 4 generates the normal output data D1out. On the other hand, the ECC generation circuit 101 in the data protection circuit 4 generates the ECC having the error (hereinafter referred to as error ECC) C1 based on the error input data D1in. In such a case, the parity check circuit 201 cannot detect the occurrence of the error ECC. However, the normal data D1out is checked using the error ECC C1 in the ECC check in the subsequent stage of the data protection circuit 4 (ECC check that is performed when the data is again read out from the memory 3). Accordingly, the error occurrence is detected throughout the data processing apparatus 1. Although the normal data D1out may be wrongly corrected with the error ECC C1 in the ECC check in the subsequent stage, such error correction can be prevented by a fourth exemplary embodiment that will be described later.

When the error is occurred in any of the paths P4 and P10, and the FF 7, the data protection circuit 4 generates the error output data D1out and normal ECC C1. Further, the parity check circuit 201 checks the error input data D1in with the normal parity C2. Accordingly, the parity check circuit 201 is able to detect that the error is occurred in the path of the previous stage.

When the error is occurred in any of the paths P5 and P11, and the FF 8, the data protection circuit 4 generates the normal output data D1out and the error ECC C1. Further, the parity check circuit 201 checks the normal input data D1in with the normal parity C2. In such a case, the parity check circuit 201 cannot detect the occurrence of the error ECC. However, the error occurrence is detected in the ECC check in the subsequent stage, as is similar to the case in which the error is occurred in the path P3.

When the error is occurred in the path P12, the data protection circuit 4 normally generates the output data D1out and the ECC C1. However, the parity check circuit 201 checks the error input data D1in with the normal parity C2. Accordingly, the parity check circuit 201 is able to detect that the error is occurred in the path of the previous stage.

When the error is occurred in the path P13, the data protection circuit 4 generates the error output data D1out and the normal ECC C1. In such a case, the data protection circuit 4 cannot detect the occurrence of the error output data. However, the error occurrence is detected in the ECC check in the subsequent stage, as is similar to the case in which the error is occurred in the path P3.

### Second Exemplary Embodiment

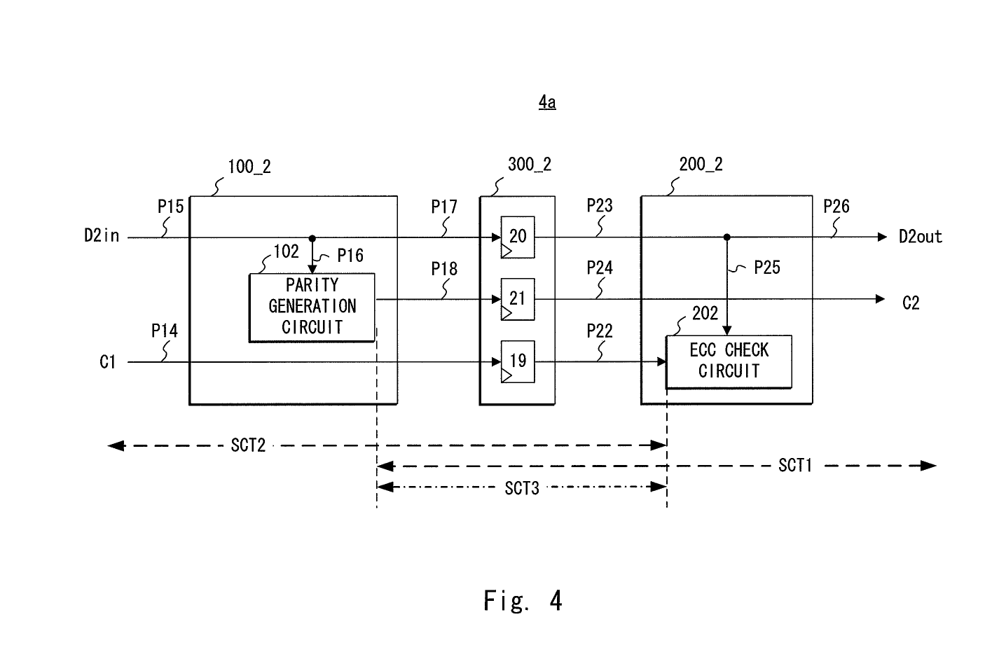

As shown in FIG. 4, a data protection circuit 4a according to the second exemplary embodiment includes an error detecting code generation unit 100_2, a data check unit 200_2, and a connection unit 300_2. The connection unit 300_2 connects the generation unit 100_2 and the check unit 200_2.

The error detecting code generation unit 100_2 includes a parity generation circuit 102. The parity generation circuit 102 generates the parity C2 corresponding to D2 in input through the memory bus B2 shown in FIG. 1. Further, the data check unit 200_2 includes an ECC check circuit 202. The ECC check circuit 202 detects the input data D2 in using the ECC C1 input according thereto.

Further, the connection unit 300_2 includes three FFs 19 to 21. The FF 19 transfers the ECC C1 that is input to the ECC check circuit 202. Further, the FF 20 supplies the input data D2in to the ECC check circuit 202 and outputs the input data D2 in as output data D2out of the data protection circuit 4a. The output data D2out is transferred to the processor 2 through the system bus B1 shown in FIG. 1. Further, the FF 21 transfers the parity C2 output from the parity generation circuit 102 to the processor 2 through the system bus B1.

Accordingly, as shown in FIG. 4, the subsequent stage of the parity generation circuit 102 corresponds to the parity protecting section SCT1, and the previous stage of the ECC check circuit 202 corresponds to the ECC protecting section SCT2. Further, the section between the parity generation circuit 102 and the ECC check circuit 202 corresponds to the overlap protecting section SCT3. In short, in the data protection circuit 4a, there is no unprotected section SCTn shown in FIG. 13 in reading the data from the memory 3. Thus, the occurrence of the invalid data can be detected with higher accuracy.

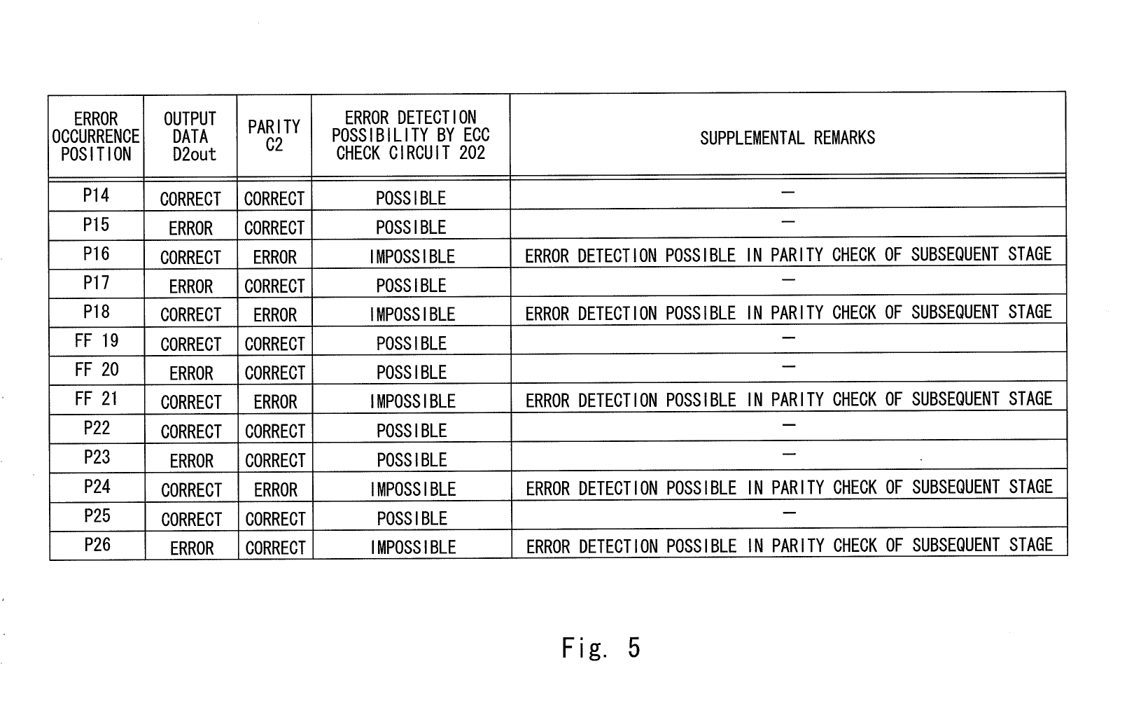

Hereinafter, the operation of this exemplary embodiment will be described with reference to FIG. 5. FIG. 5 shows an operation example when one-bit error is occurred in each of paths P14 to P18 and P22 to P26, and FFs 19 to 21 shown in FIG. 4.

When the error is occurred in any of the paths P14 (including the memory bus B2) and P22, and the FF 19, the data protection circuit 4a normally generates the output data D2out and the parity C2. Further, the ECC check circuit 202 in the data protection circuit 4a checks the input data D2 in using the error ECC C1. Accordingly, the ECC check circuit 202 is able to detect that the error is occurred in the path of the previous stage.

When the error is occurred in the path P15 (including the memory bus B2), the data protection circuit 4a generates the error output data D2out. Further, the parity generation circuit 102 in the data protection circuit 4a treats the error input data D2 in as the normal data, and normally generates the parity C2. However, the ECC check circuit 202 checks the error input data D2 in using the normal ECC C1. Accordingly, the ECC check circuit 202 is able to detect that the error is occurred in the path of the previous stage.

When the error is occurred in the path P16, the data protection circuit 4a generates the normal output data D2out. On the other hand, the parity generation circuit 102 generates the error parity C2 based on the error input data D2in. In such a case, the ECC check circuit 202 cannot detect the occurrence of the error parity. However, the normal data D2out is checked using the error parity C2 in the parity check in the subsequent stage of the data protection circuit 4a. Accordingly, the error occurrence is detected throughout the data processing apparatus 1.

When the error is occurred in any of the paths P17 and P23, and the FF 20, the data protection circuit 4a generates the error output data D2out and the normal parity C2. Further, the ECC check circuit 202 checks the error input data D2 in using the normal ECC C1. Accordingly, the ECC check circuit 202 is able to detect that the error is occurred in the path of the previous stage.

When the error is occurred in any of the paths P18 and P24, and the FF 21, the data protection circuit 4a generates the normal output data D2out and the error parity C2. Further, the ECC check circuit 202 checks the error input data D2 in using the normal ECC C1. In such a case, the ECC check circuit 202 cannot detect the occurrence of the error ECC. However, the error occurrence is detected in the parity check in the subsequent stage, as is similar to the case in which the error is occurred in the path P16.

When the error is occurred in the path P25, the data protection circuit 4a normally generates the output data D2out and the parity C2. Further, the ECC check circuit 202 checks the error input data D2 in using the normal ECC C1. Accordingly, the ECC check circuit 202 is able to detect that the error is occurred in the path of the previous stage.

When the error is occurred in the path P26, the data protection circuit 4a generates the error output data D2out and the normal parity C2. In such a case, the data protection circuit 4a cannot detect the occurrence of the error output data. However, the error occurrence is detected in the parity check in the subsequent stage, as is similar to the case in which the error is occurred in the path P16.

### Third Exemplary Embodiment

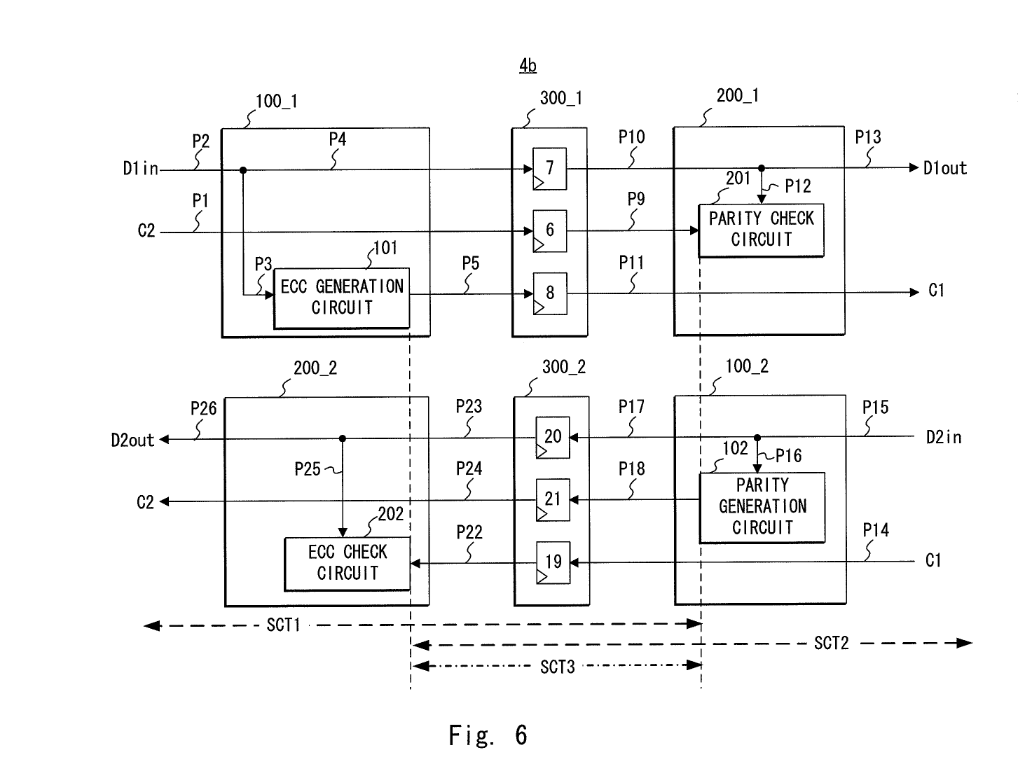

As shown in FIG. 6, a data protection circuit 4b according to the third exemplary embodiment includes the error detecting code generation unit 100_1, the data check unit 200_1, and the connection unit 300_1 shown in FIG. 2, and the error detecting code generation unit 100_2, the data check unit 200_2, and the connection unit 300_2 shown in FIG. 4 in parallel.

Accordingly, as shown in FIG. 6, the overlap protecting section SCT3 is formed. In short, in the data protection circuit 4b, there is no unprotected section SCTn shown in FIG. 13 in writing/reading data to/from the memory 3.

### Fourth Exemplary Embodiment

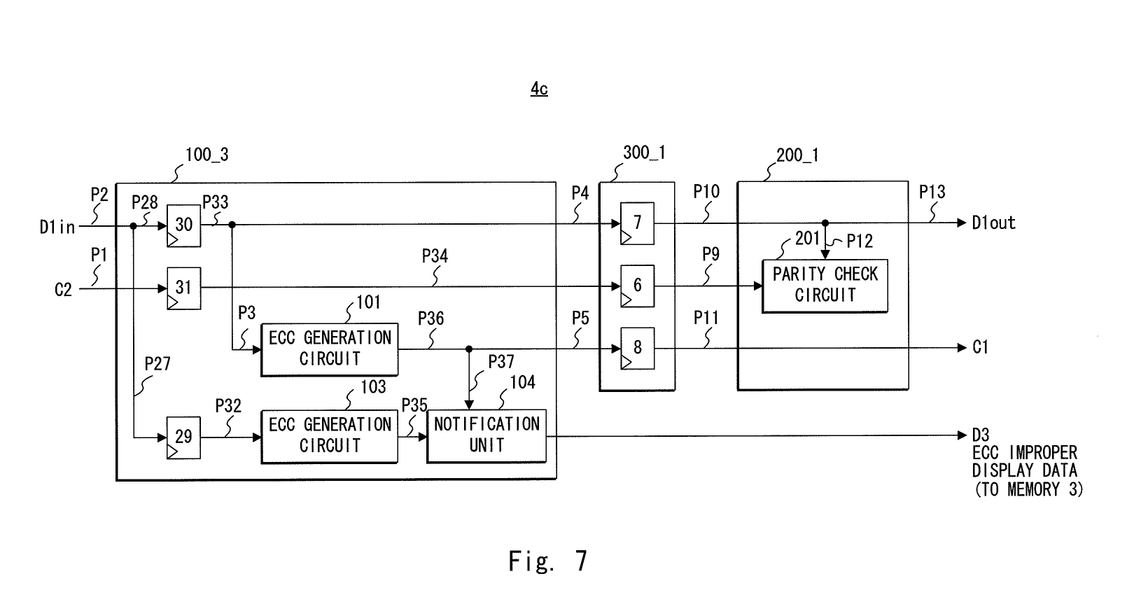

As shown in FIG. 7, a data protection circuit 4c according to the fourth exemplary embodiment is different from the circuit of the above-mentioned first exemplary embodiment in that an error detecting code generation unit 100_3 is provided instead of the error detecting code generation unit 100_1 shown in FIG. 2.

Further, the error detecting code generation unit 100_3 includes the ECC generation circuit 101 which is similar to that shown in FIG. 2, an ECC generation circuit 103, and a notification unit 104. The ECC generation circuit 103 is arranged to be parallel with the ECC generation circuit 101, and generates the ECC C1 corresponding to the input data D1in. The notification unit 104 notifies an external part of data indicating that the ECC C1 is not suitable to be used for error correction of the output data D1out (hereinafter referred to as ECC improper display data) D3 when the ECC C1 generated by the generation circuit 101 does not match the ECC C1 generated by the generation circuit 103. In the example shown in FIG. 7, the notification unit 104 stores the ECC improper display data D3 in the memory 3. Further, the timing of inputting the data D1in to the ECC generation circuits 101 and 103 is synchronized by the FFs 29 and 30. In accordance with this, the timing of transferring the parity C2 that is input is delayed by the FF 31. Note that the FFs 29 to 31 are not necessarily provided.

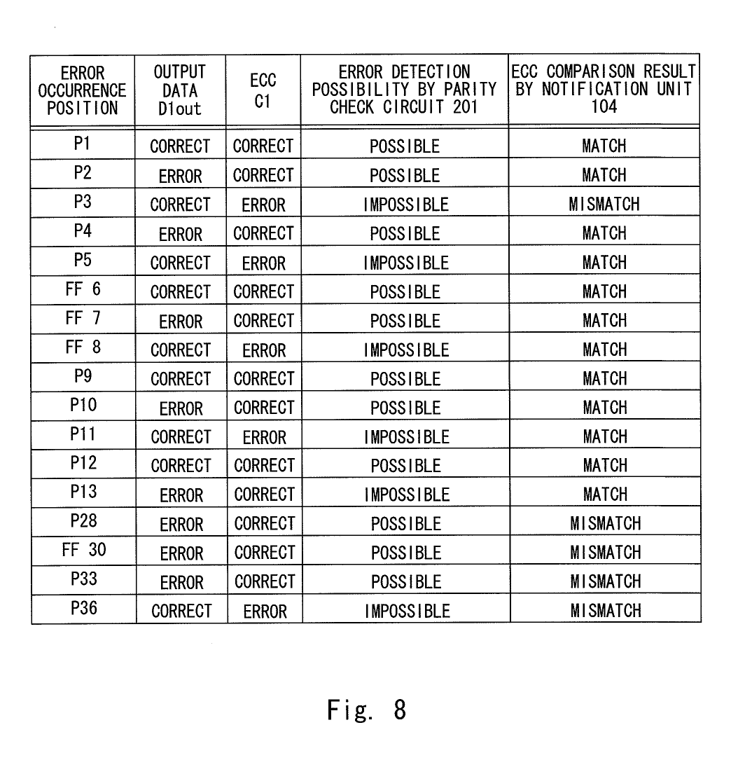

Hereinafter, the operation according to this exemplary embodiment will be described with reference to FIG. 8. FIG. 8 shows an operation example when one-bit error is occurred in each of the paths P1 to P5, P10 to P13, P28, P33, and P36, and the FFs 6 to 9 and 30 shown in FIG. 7. Further, the output data D1out, the ECC C1, and the error detection possibility by the parity check circuit 201 when the error is occurred in each of the paths P1 to P5 and P10 to P13, and the FFs 6 to 9 are similar to those shown in FIG. 3, and thus the description will be omitted.

When the error is occurred in any of the paths P1, P2, P4, P5, and P10 to P13, and the FFs 6 to 9, each of the ECC generation circuits 101 and 103 in the data protection circuit 4c generates the same ECC C1. Accordingly, the notification unit 104 detects that both ECC C1 are matched each other, and does not generate the ECC improper display data D3.

On the other hand, when the error is occurred in any of the paths P3, P28, P33, and P36, and the FF 30, the notification unit 104 detects the mismatch of the both ECC C1, and stores the ECC improper display data D3 in the memory 3. Thus, the ECC improper display data D3 can be referred in the ECC check in the subsequent stage of the data protection circuit 4c (ECC check that is performed when data is again read out from the memory 3), thereby preventing the normal data D1out from being corrected to the invalid data using the error ECC C1.

### Fifth Exemplary Embodiment

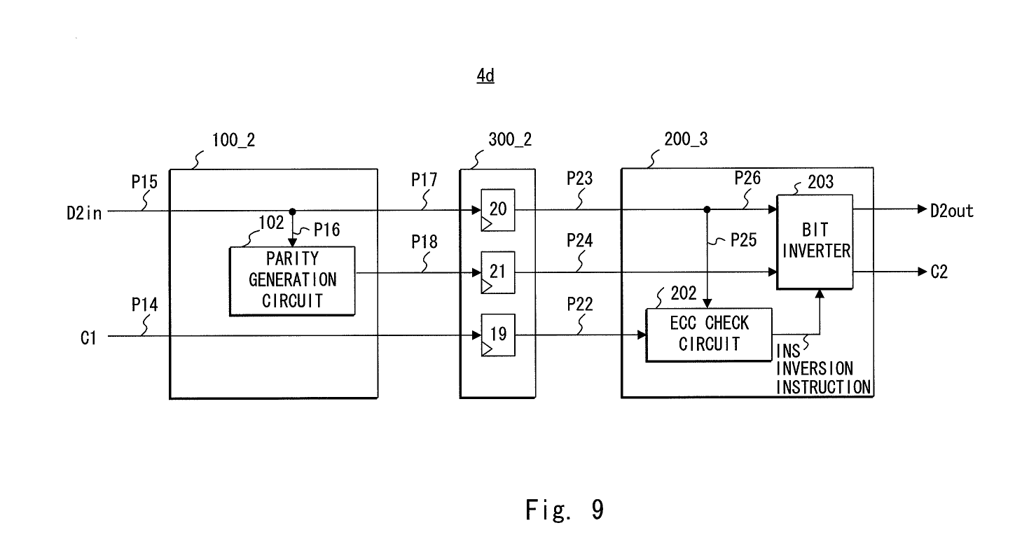

As shown in FIG. 9, a data protection circuit 4d according to the fifth exemplary embodiment is different from the data protection circuit 4a according to the above-mentioned second exemplary embodiment in that a data check unit 200_3 is provided instead of the data check unit 200_2 shown in FIG. 4.

Further, the data check unit 200_3 includes the ECC check circuit 202 which is similar to that shown in FIG. 4, and a bit inverter 203. The bit inverter 203 inverts the bits of the output data D2out and the parity C2 in accordance with an inversion instruction INS from the ECC check circuit 202.

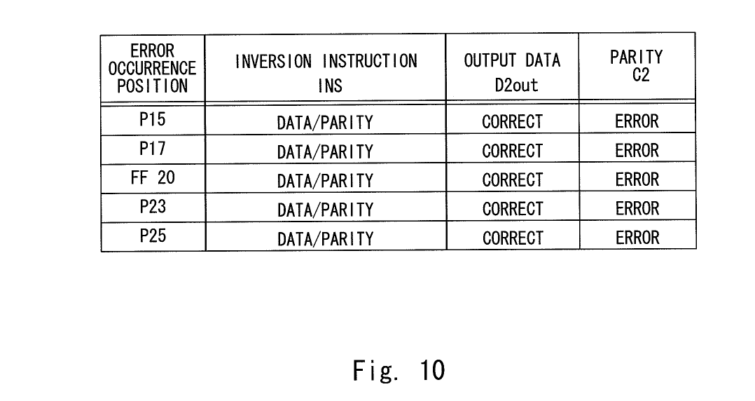

Hereinafter, the operation according to this exemplary embodiment will be described with reference to FIG. 10. FIG. 10 shows an operation example when one-bit error is occurred in each of the paths P15, P17, P23, and P25, and the FF 20 shown in FIG. 9.

When the error is occurred in any of the paths P15 (including the memory bus B2), P17, P23, and P25, and the FF 20, the ECC check circuit 202 checks the error input data D2 in using the normal ECC C1, and detects that the error is occurred in the path of the previous stage. At this time, the ECC check circuit 202 supplies the inversion instruction INS to the bit inverter 203, so as to make the bit inverter 203 output the normal output data D2out and the error parity C2. Note that the ECC check circuit 202 specifies the bit of the input data D2 in that should be corrected (inverted) and the bit of the parity C2 corresponding to it that should be inverted as the inversion instruction INS.

As stated above, the data protection circuit 4d forces to invert the parity and gives notice of a path error. Accordingly, even when the normal data and the ECC are output (which means when the circuit in the subsequent stage can be normally operated), the error occurrence can be detected in the parity check in the subsequent stage. Further, such a notification mechanism of the path error is useful for analyzing malfunction of the data processing apparatus 1 (identifying error occurrence position, and analyzing data access pattern upon occurrence of an error) or the like.

### Sixth Exemplary Embodiment

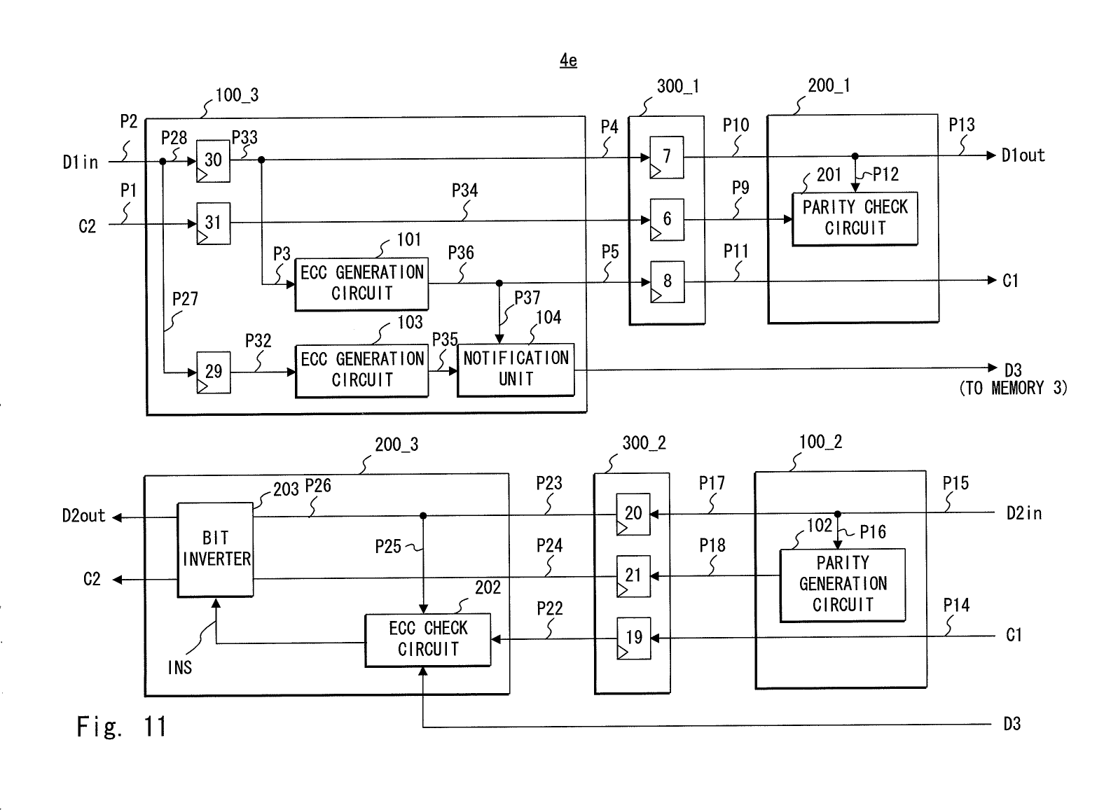

As shown in FIG. 11, a data protection circuit 4e according to the sixth exemplary embodiment includes the error detecting code generation unit 100_3, the data check unit 200_1, and the connection unit 300_1 shown in FIG. 7, and the error detecting code generation unit 100_2, the data check unit 200_3, and the connection unit 300_2 shown in FIG. 9 in parallel. Note that the ECC check circuit 202 in the data check unit 200_3 refers to the ECC improper display data D3 stored in the memory 3 by the notification unit 104.

In operation, the ECC check circuit 202 reads out the ECC improper display data D3 corresponding to the input data D2 in which should be checked from the memory 3. When the ECC improper display data D3 indicates mismatch of the ECC in the notification unit 104, the ECC check circuit 202 does not produce the inversion instruction INS even when the correction of the input data D2 in using the ECC C1 is possible, thereby preventing the normal data from being wrongly corrected.

The first to sixth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A data protection circuit to which first input data and a first error detecting code are input, the data protection circuit outputting first output data corresponding to the first input data and a second error detecting code, the data protection circuit comprising:
a first path that outputs the first input data as the first output data;
a first generation unit that acquires the first input data from the first path and generates the second error detecting code; and
a first check unit that acquires the first input data from a position on the first path that is closer to an output side than an acquiring position in the first generation unit and checks the first input data using the first error detecting code.

2. The data protection circuit according to claim 1, wherein a connection unit that connects the acquiring position in the first generation unit and an acquiring position in the first check unit is further provided in the first path so that the first input data is acquired by the first check unit subsequent to acquirement by the first generation unit.

3. The data protection circuit according to claim 1, wherein
the second error detecting code comprises an error correcting code corresponding to the first output data, and
the first generation unit comprises:
a second generation unit that acquires the first input data from one position on the first path, generates the second error detecting code, and externally outputs the generated second error detecting code;
a third generation unit that acquires the first input data from another position on the first path, and generates the second error detecting code; and
a notification unit that notifies an external part that the second error detecting code is not suitable to be used for error correction of the first output data upon detecting mismatch between error detecting codes generated by the second and the third generation units.

4. The data protection circuit according to claim 1, wherein
the first error detecting code comprises an error correcting code corresponding to the first input data, and
the first check unit corrects the first input data and changes the second error detecting code according to the corrected position in the first input data upon detecting an error in the first input data that can be corrected using the first error detecting code.

5. The data protection circuit according to claim 1, further comprising:
a second path that outputs second input data as second output data;
a second generation unit that acquires the second input data from the second path and generates the first error detecting code; and
a second check unit that acquires the second input data from a position on the second path that is closer to an output side than an acquiring position in the second generation unit, and checks the second input data with a second error detecting code that is input according to the second input data.

6. The data protection circuit according to claim 5, wherein a connection unit that connects the acquiring position in the second generation unit and an acquiring position in the second check unit is further provided in the second path so that the second input data is acquired by the second check unit subsequent to acquirement by the second generation unit.

7. The data protection circuit according to claim 5, wherein
the second error detecting code comprises an error correcting code corresponding to the first output data,
the first generation unit comprises:
a third generation unit that acquires the first input data from one position on the first path, generates the second error detecting code, and externally outputs the generated second error detecting code;
a fourth generation unit that acquires the first input data from another position on the first path and generates the second error detecting code; and
a storing unit that externally stores that the second error detecting code is not suitable to be used for error correction of the first output data upon detection of mismatch between both error detecting codes generated by the third and the fourth generation units, and
the second check unit corrects the second input data when the second check unit itself detects an error that can be corrected with a second error detecting code that corresponds to the second input data and the second error detecting code is not stored as not being suitable for the error correction.

8. A data processing apparatus comprising:
first and second processing circuits, each of which processing data; and
a protection circuit to which data and a first error detecting code are input from the first processing circuit, the protection circuit outputting the data and a second error detecting code to the second processing circuit, wherein
the protection circuit generates the second error detecting code corresponding to the data, and thereafter checks the data using the first error detecting code.

9. A data protection method comprising:
generating a first error detecting code corresponding to data that is input, and then checking the data using a second error detecting code input according to the data.

10. The data protection method according to claim 9, comprising:
using an error detecting code that comprises an error correcting code corresponding to the data as the first error detecting code;
generating the first error detecting code for each of two positions that are different from each other on a transfer path of the data; and
determining that the first error detecting code is not suitable to be used for error correction of the data upon detecting mismatch between the error detecting codes that are generated.

11. The data protection method according to claim 10, comprising:
determining whether there is an error in data that can be corrected using the first error detecting code when data check using the first error detecting code is required; and
correcting the data when it is determined that there is the error that can be corrected and it is not determined that the first error detecting code is not suitable to be used for error correction in generating the first error detecting code.

12. The data protection method according to claim 9, comprising:
using an error detecting code that comprises an error correcting code corresponding to the data as the second error detecting code; and
correcting the data and changing the first error detecting code according to the corrected position in the data, upon detecting an error in the data that can be corrected using the second error detecting code.
